(19) United States
(12) Patent Application Publication
(10) Pub. No.: US 2004/0195666 A1
(43) Pub. Date: Oct. 7, 2004

(54) Stacked module systems and methods

(76) Inventors: Julian Partridge, Austin, TX (US); James Douglas Wehrly JR., Austin, TX (US)

Correspondence Address: J. Scott Denko, Andrews & Kurth, L.L.P., Suite 1700, 111 Congress Ave., Austin, TX, 78701, US

(21) Appl. No.: 10/828,495

(22) Filed: Apr. 20, 2004

Related U.S. Application Data
(63) Continuation-in-part of application No. PCT/US03/29000, filed on Sep. 15, 2003.
Application No. PCT/US03/29000 is a continuation-in-part of application No. 10/453,398, filed on Jun. 3, 2003.
Application No. 10/453,398 is a continuation-in-part of application No. 10/005,581, filed on Oct. 26, 2001, now Pat. No. 6,576,992.

(51) Int. Cl. H01L 23/02

(52) U.S. Cl. 257/685

(57) ABSTRACT

The present invention stacks chip scale-packaged integrated circuits (CSPs) into modules that conserve PWB or other board surface area. In a preferred embodiment in accordance with the invention, a form standard is disposed between the flex circuitry and the IC package over which a portion of the flex circuitry is laid. The form standard provides a physical form that allows many of the varying package sizes found in the broad family of CSP packages to be used to advantage while employing a standard connective flex circuitry design. In a preferred embodiment, the form standard will be bonded to the flex circuitry with metallurgical bonds devised from an intermetallic that improves module stability while lowering the module profile.

### RELATED APPLICATIONS

This application is a continuation-in-part of U.S. patent application Ser. No. 10/453,398, filed Jun. 3, 2003, which is a continuation-in-part of U.S. patent application Ser. No. 10/005,581, filed Oct. 26, 2001, now U.S. Pat. No. 6,576,992 and a continuation-in-part of PCT App. No. PCT/US03/29000, filed Sep. 15, 2003.

U.S. patent application Ser. No. 10/453,398, filed Jun. 3, 2003, is hereby incorporated by reference.

PCT Pat. App. No. PCT/US03/29000, filed Sep. 15, 2003, is hereby incorporated by reference.

### TECHNICAL FIELD

The present invention relates to aggregating integrated circuits and, in particular, to stacking integrated circuits in chip-scale packages.

### BACKGROUND OF THE INVENTION

A variety of techniques are used to stack packaged integrated circuits. Some methods require special packages, while other techniques stack conventional packages.

The predominant package configuration employed during the past decade has encapsulated an integrated circuit (IC) in a plastic surround typically having a rectangular configuration. The enveloped integrated circuit is connected to the application environment through leads emergent from the edge periphery of the plastic encapsulation. Such “leaded packages” have been the constituent elements most commonly employed by techniques for stacking packaged integrated circuits.

Leaded packages play an important role in electronics, but efforts to miniaturize electronic components and assemblies have driven development of technologies that preserve circuit board surface area. Because leaded packages have leads emergent from peripheral sides of the package, leaded packages occupy more than a minimal amount of circuit board surface area. Consequently, alternatives to leaded packages known as chip scale packaging or “CSP” have recently gained market share.

CSP refers generally to packages that provide connection to an integrated circuit through a set of contacts (often embodied as “bumps” or “balls”) arrayed across a major surface of the package. Instead of leads emergent from a peripheral side of the package, contacts are placed on a major surface and typically emerge from the planar bottom surface of the package. The absence of “leads” on package sides renders most stacking techniques devised for leaded packages inapplicable for CSP stacking.

A variety of previous techniques for stacking CSPs typically present complex structural arrangements and thermal or high frequency performance issues. For example, thermal performance is a characteristic of importance in CSP stacks.

What is needed, therefore, is a technique and system for stacking CSPs that provides a thermally efficient, reliable structure that performs well at higher frequencies but does not add excessive height to the stack yet allows production at reasonable cost with readily understood and managed materials and methods.

### SUMMARY OF THE INVENTION

The present invention stacks chip scale-packaged integrated circuits (CSPs) into modules that conserve PWB or other board surface area. Although the present invention is applied most frequently to chip scale packages that contain one die, it may be employed with chip scale packages that include more than one integrated circuit die. Multiple numbers of CSPs may be stacked in accordance with the present invention. The CSPs employed in stacked modules devised in accordance with the present invention are connected with flex circuitry. That flex circuitry may exhibit one or two or more conductive layers.

A form standard is disposed between the flex circuitry and the IC package over which a portion of the flex circuitry is laid. The form standard can take many configurations and may be used where flex circuitry is used to connect CSPs to one another in stacked modules having two or more constituent ICs. The form standard provides a physical form that allows many of the varying package sizes found in the broad family of CSP packages to be used to advantage while employing a standard connective flex circuitry design. In a preferred embodiment, the form standard will be devised of heat transference material, a metal, for example, such as copper would be preferred, to improve thermal performance.

In constructing modules in accordance with some preferred modes of the invention, when attaching the form standard to the flex circuitry, metallurgical bonds are created between flex circuitry and the form standard.

### SUMMARY OF THE DRAWINGS

FIG. 1 is an elevation view of a high-density circuit module devised in accordance with a preferred two-high embodiment of the present invention.

FIG. 2 depicts, in enlarged view, the area marked “A” in FIG. 1.

FIG. 3 depicts a preferred construction method that may be employed in making a high-density module devised in accordance with a preferred embodiment of the present invention.

FIG. 4 depicts a preferred construction method that may be employed in making a high-density module devised in accordance with a preferred embodiment of the present invention.

FIG. 5 depicts a unit that may be employed in a module devised in accordance with a preferred embodiment of the present invention.

### DESCRIPTION OF PREFERRED EMBODIMENTS

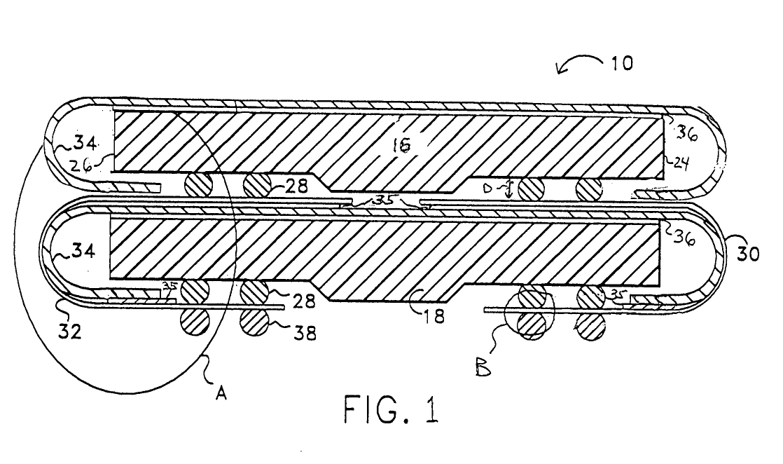

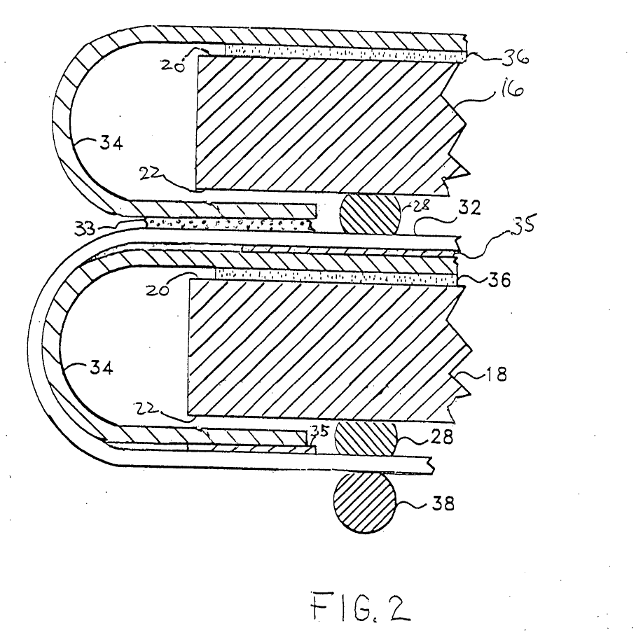

FIG. 1 shows a two-high module 10 devised in accordance with a preferred embodiment of the invention. FIG. 1 has an area marked “A” that is subsequently shown in enlarged depiction in FIG. 2. Module 10 is comprised of two CSPs: CSP 16 and CSP 18. Each of the CSPs has an upper surface 20 and a lower surface 22 and opposite lateral edges 24 and 26 and typically include at least one integrated circuit surrounded by a plastic body 27. The body need not be plastic, but a large majority of packages in CSP technologies are plastic. Those of skill will realize that the present invention may be devised to create modules with different size CSPs and that the constituent CSPs may be of different types within the same module 10. For example, one of the constituent CSPs may be a typical CSP having lateral edges 24 and 26 that have an appreciable height to present a “side” while other constituent CSPs of the same module 10 may be devised in packages that have lateral edges 24 and 26 that are more in the character of an edge rather than a side having appreciable height.

The term CSP should be broadly considered in the context of this application. Collectively, these will be known herein as chip scale packaged integrated circuits (CSPs) and preferred embodiments will be described in terms of CSPs, but the particular configurations used in the explanatory figures are not, however, to be construed as limiting. For example, the elevation views are depicted with CSPs of a particular profile known to those in the art, but it should be understood that the figures are exemplary only. The invention may be employed to advantage in the wide range of CSP configurations available in the art where an array of connective elements is available from at least one major surface. The invention is advantageously employed with CSPs that contain memory circuits, but may be employed to advantage with logic and computing circuits where added capacity without commensurate PWB or other board surface area consumption is desired.

Typical CSPs, such as, for example, ball-grid-array (“BGA”), micro-ball-grid array, and fine-pitch ball grid array (“FBGA”) packages have an array of connective contacts embodied, for example, as leads, bumps, solder balls, or balls that extend from lower surface 22 of a plastic casing in any of several patterns and pitches. An external portion of the connective contacts is often finished with a ball of solder. Shown in FIG. 1 are contacts 28 along lower surfaces 22 of the illustrated constituent CSPs 16 and 18. Contacts 28 provide connection to the integrated circuit or circuits within the respective packages. As shown in FIG. 1, as to CSP 16, contacts 28 exhibit a height denoted by reference D.

In FIG. 1, flex circuitry (“flex”, “flex circuits” or “flexible circuit structures”) is shown connecting constituent CSPs 16 and 18. A single flex circuit may be employed in place of the two depicted flex circuits 30 and 32. The entirety of the flex circuitry may be flexible or, as those of skill in the art will recognize, a PCB structure made flexible in certain areas to allow conformability around CSPs and rigid in other areas for planarity along CSP surfaces may be employed as an alternative flex circuit in the present invention. For example, structures known as rigid-flex may be employed.

A first form standard 34 is shown disposed adjacent to upper surface 20 of CSP 18. A second form standard is also shown associated with CSP 16. Form standard 34 may be fixed to upper surface 20 of the respective CSP with an adhesive 36 which preferably is thermally conductive. Form standard 34 may also, in alternative embodiments, merely lay on upper surface 20 or be separated from upper surface 20 by an air gap or medium such as a thermal slug or non-thermal layer. A form standard may be employed on each CSP in module 10 for heat extraction enhancement as shown in the depiction of FIG. 1 which is a preferred mode for the present invention where heat extraction is a high priority. In other embodiments, form standard 34 may be inverted relative to the corresponding CSP so that, for example, it would be opened over the upper surface 20 of CSP 18.

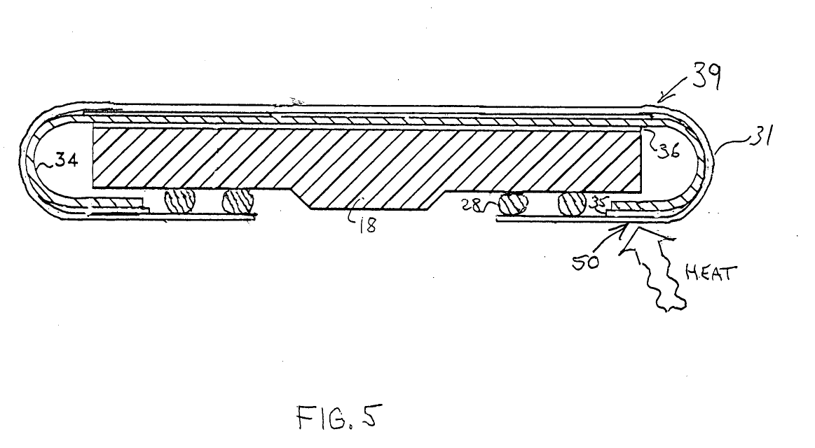

Form standard 34 is, in a preferred embodiment, devised from copper to create, as shown in the depicted preferred embodiment of FIG. 1, a mandrel that mitigates thermal accumulation while providing a standard sized form about which flex circuitry is disposed. Form standard 34 may also be devised from nickel plated copper in preferred embodiments. Form standard 34 may take other shapes and forms such as, for example, an angular “cap” that rests upon the respective CSP body. It also need not be thermally enhancing although such attributes are preferable. The form standard 34 allows the invention to be employed with CSPs of varying sizes, while articulating a single set of connective structures useable with the varying sizes of CSPs. Thus, a single set of connective structures such as flex circuits 30 and 32 (or a single flexible circuit in the mode where a single flex is used in place of the flex circuit pair 30 and 32 as shown in FIG. 5) may be devised and used with the form standard 34 method and/or systems disclosed herein to create stacked modules with CSPs having different sized packages. This will allow the same flex circuitry set design to be employed to create iterations of a stacked module 10 from constituent CSPs having a first arbitrary dimension X across attribute Y (where Y may be, for example, package width), as well as modules 10 from constituent CSPs having a second arbitrary dimension X prime across that same attribute Y. Thus, CSPs of different sizes may be stacked into modules 10 with the same set of connective structures (i.e., flex circuitry). Further, as those of skill will recognize, mixed sizes of CSPs may be implemented into the same module 10, such as would be useful to implement embodiments of a system-on-a-stack such as those disclosed in co-pending application PCT/US03/29000, filed Sep. 15, 2003, which is hereby incorporated by reference and commonly owned by the assignee of the present application.

In one preferred embodiment, portions of flex circuits 30 and 32 are fixed to form standard 34 by bonds 35 which, are in some preferred modes, metallurgical bonds created by placing on form standard 34, a first metal layer such as tin, for example, which, when melted, combines with a second metal that was placed on the flex circuitry or is part of the flex circuitry (such as the gold plating on a conductive layer of the flex) to form a higher melting point intermetallic bond that will not remelt during subsequent reflow operations as will be described further.

FIG. 2 depicts in enlarged view, the area marked “A” in FIG. 1. FIG. 2 illustrates in a preferred embodiment, an arrangement of a form standard 34 and its relation to flex circuitry 32 in a two-high module 10 that employs a form standard 34 with each of CSPs 16 and 18. The internal layer constructions of flex circuitry 32 are not shown in this figure. Shown in greater detail than in FIG. 1 are bonds 35 that will be described with reference to later Figs. Also shown in FIG. 2 is an application of adhesive 36 between form standards 34 and CSPs 18 and 16. In a preferred embodiment, an adhesive 33 may also be employed between form standard 34 associated with CSP 16 and the flex circuitry 32 that is about form standard 34 associated with CSP 18. Adhesive 33 will preferably be thermally conductive.

Although those of skill will recognize that the Figs. are not drawn to scale, the depicted contact 28 of CSP 18 has been shown (although need not exhibit in every embodiment) to have a height greater than contact 28 would have before CSP 18 was incorporated in module 10. This is a result of and allowed by preferred methods for devising modules 10 as are now described.

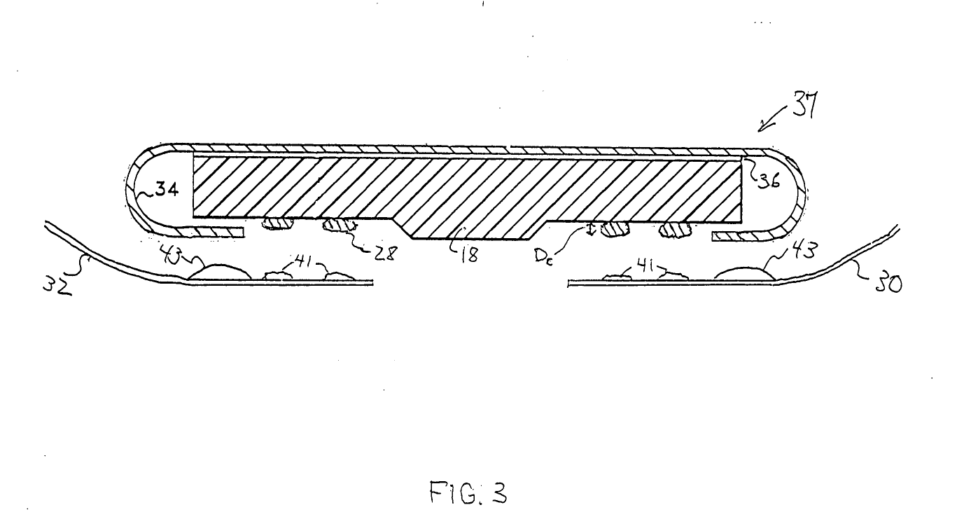

With reference to FIG. 3, combination 37 is depicted as consisting of form standard 34 attached to CSP 18 which, when attached to flex circuitry, is adapted to be employed in module 10. The attachment of form standard 34 to CSP 18 may be realized with adhesive depicted by reference 36 which is preferably a film adhesive that is applied by heat tacking either to form standard 34 or CSP 18. A variety of other methods may be used to adhere form standard 34 to CSP 18 and in some embodiments, no adhesion may be used

As further depicted in FIG. 3, flex circuits 30 and 32 are prepared for attachment to combination 37 by the application of solder paste 41 at sites that correspond to contacts 28 of CSP 18 to be connected to the flex circuitry. Also shown are glue applications indicated by references 43 which are, when glue is employed to attach form standard 34 to the flex circuitry, preferably liquid glue.

As shown in this embodiment, contacts 28 of CSP 18 have height Dc which is less than height D shown in earlier FIG. 2. The depicted contacts 28 of CSP 18 are reduced in height by compression or other means of height reduction before attachment of combination 37 to the flex circuitry. This compression may be done before or after attachment of form standard 34 and CSP 18 with after-attachment compression being preferred. Contacts 28 may be reduced in height while in a solid or semi-solid state. Unless reduced in height, contacts 28 on CSP 18 tend to “sit-up” on solder paste sites 41 during creation of module 10. This causes the glue line between the flex circuitry and form standard 34 to be thicker than may be desired. The glue reaches to fill the gap between the flex and form standard 34 that results from the distancing of the attached form standard 34 from the flex by the contacts 28 “sitting” upon the solder paste sites 41.

With a thicker glue line between flex and form standard 34, upon reflowing, the solder in contacts 28 mixes with solder paste 41 and reaches to span the space between CSP 18 and the flex circuitry which is now a fixed distance away from CSP 18. This results in a larger vertical dimension for contact 28 than is necessary due to the higher glue line and, consequently, a module 10 with a taller profile. The higher glue line was created by not reducing the contact diameters before attachment of the flex circuitry to the form standard 34 (or the form standard part of combination 37). With the preferred methods of the present invention, however, upon reflow, the compressed contacts 28 mix with solder paste 41 and set beneficially as lower diameter contacts 28. The resulting unit combining combination 37 with flex circuitry may then be employed to create low profile embodiment of module 10.

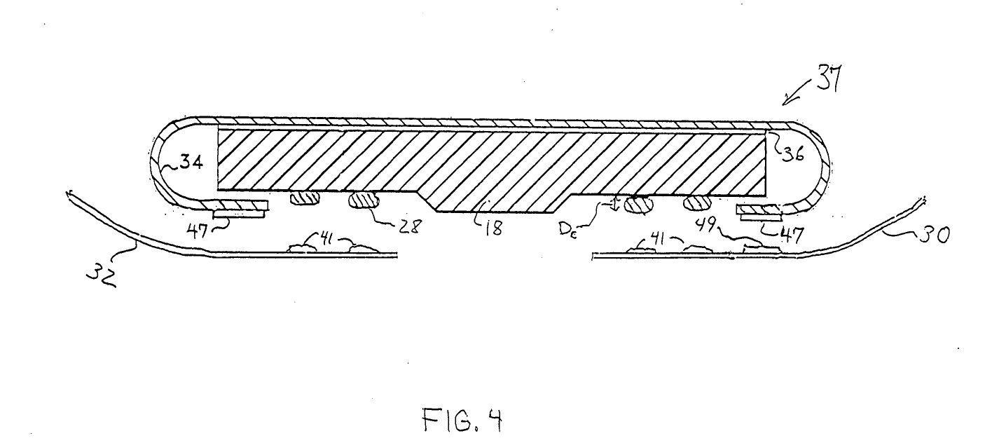

FIG. 4 depicts a preferred alternative and additional method to reduce module 10 height while providing a stable bond 35 between form standard 34 and the flex circuitry. The preferable bonds 35 that were earlier shown in FIG. 1 may be created by the following technique. As shown in FIG. 4, a first metallic material indicated by reference 47 has been layered on, or appended or plated to form standard 34. A second metallic material represented by reference 49 on flex circuit 30 is provided by, for example, applying a thin layer of metal to flex circuit 30 or, by exposing part of a conductive layer of the flex circuit. When form standard 34 is brought into proximity with the flex circuitry, and localized heating is applied to the area where the first and second metals 47 and 49 are adjacent, an intermetallic bond 35 is created. A preferred metallic material 47 would be a thin layer of tin applied to create a layer about 0.0005″. When melted to combine with the gold of a conductive layer of flex circuitry exposed at that, for example, site, the resulting intermetallic bond 35 will have a higher melting point resulting in the additional advantage of not re-melting during subsequent re-flow operations at particular temperatures.

A variety of methods may be used to provide the localized heating appropriate to implement the metallic bonding described here including localized heat application with which many in the art are familiar as well as ultrasonic bonding methods where the patterns in the flex circuitry are not exposed to the vibration inherent in such methods and the metals chosen to implement the bonds have melting points within the range achieved by the ultrasonic method.

FIG. 5 depicts unit 39 comprised from flex circuitry 31 which, in this depicted embodiment, is a single flex circuit, and form standard 34 and CSP 18. Heat is shown as being applied to area 50 where the first metallic material 47 and second metallic material 49 were made adjacent by bringing combination 37 and flex circuitry 31 together.

The creation of intermetallic bonds may also be employed to bond combination 37 to flex circuitry along other sites where form standard 34 and flex circuitry are adjacent such as, for example, on sites or continuously along the top side of form standard where typically glue is otherwise applied to further fasten flex circuitry to form standard 34. The intermetallic bonding described here may be employed alone or with other methods such as the contact compression techniques described herein to create instances of module 10 that present a low profile.

In a preferred embodiment, flex circuits 30 and 32 are multi-layer flexible circuit structures that have at least two conductive layers. Other embodiments may, however, employ flex circuitry, either as one circuit or two flex circuits to connect a pair of CSPs, that have only a single conductive layer and may exhibit the variety of simple construction parameters that are known to those of skill in the art with such features as covercoats on one, both or neither side.

Preferably, the conductive layers are metal such as alloy 110 and as those of skill will know, often have conductive areas plated with gold. The use of plural conductive layers provides advantages and the creation of a distributed capacitance across module 10 intended to reduce noise or bounce effects that can, particularly at higher frequencies, degrade signal integrity, as those of skill in the art will recognize. Module 10 of FIG. 1 has plural module contacts 38. In embodiments where module 10 includes more than two IC's, there may be found connections between flex circuits which are typically balls but may be low profile contacts constructed with pads and/or rings that are connected with solder paste applications to appropriate connections. Appropriate fills can provide added structural stability and coplanarity where desired and, depending upon the fill, can improve thermal performance.

Although the present invention has been described in detail, it will be apparent to those skilled in the art that the invention may be embodied in a variety of specific forms and that various changes, substitutions and alterations can be made without departing from the spirit and scope of the invention. The described embodiments are only illustrative and not restrictive and the scope of the invention is, therefore, indicated by the following claims.

1. A high-density circuit module comprising:
a first CSP;
a second CSP disposed above the first CSP in stacked disposition;
a first form standard disposed, in substantial part, above the first CSP;
flex circuitry connecting the first and second CSPs and positioned to be, in part, beneath the first CSP and, in part, above the first form standard and beneath the second CSP; and
at least one metallic bond attaching the flex circuitry and the first form standard.

2. The high-density circuit module of claim 1 further comprising a second form standard disposed, in substantial part, above the second CSP.

3. The high-density circuit module of claim 1 in which the flex circuitry is comprised of a first flex circuit and a second flex circuit which are each attached to the first form standard with at least one metallic bond.

4. The high-density circuit module of claim 1 further comprising a second form standard and in which the flex circuitry is comprised of a first flex circuit and a second flex circuit which are each attached to the first form standard with at least one metallic bond.

5. The high-density circuit module of claim 1 in which the metallic bond comprises tin and gold.

6. The high-density circuit module of claim 1 in which the metallic bond is created by combining a first metallic material applied to the first form standard and a second metallic material from which the flex circuitry is comprised.

7. The high-density circuit module of claim 6 in which the combining of the first metallic material and the second metallic material is achieved through a selected application of heat.

8. The high-density circuit module of claim 7 in which the selected application of heat is achieved with localized friction heating.

9. A high-density circuit module comprising:
a first CSP;
a second CSP stacked above the first CSP;
a first form standard associated with the first CSP; and
a second form standard associated with the second CSP.

10. The high-density module of claim 9 further comprising flex circuitry connecting the first and second CSPs.

11. The high density module of claim 10 in which the flex circuitry is comprised of first and second flex circuits.

12. The high-density module of claim 10 in which the flex circuitry is attached to the first form standard with at least one metallic bond.

13. The high-density module of claim 12 in which the metallic bond is comprised of a first metallic material and a second metallic material.

14. The high-density module of claim 13 in which the first metallic material is comprised of tin and the second metallic material is comprised of gold.

15. The high-density module of claim 12 in which the metallic bond is realized by selective application of heat.

16. The high-density module of claim 13 in which the flex circuitry is comprised of a first flex circuit and a second flex circuit and each of the first and second flex circuits is attached to the first form standard with at least one metallic bond.

17. The high-density module of claim 10 in which the flex circuitry is attached to the first form standard with adhesive.

18. A method creating a high-density circuit module comprising the steps of:
providing a form standard
providing first and second CSPs;
attaching the form standard to the first CSP;
applying a first metallic material to at least one part of the first form standard;
providing flex circuitry with an area where flex metallic material is exposed;
disposing the flex circuitry adjacent to the first form standard to create an area of contact between the flex metallic material and the first metallic material;
selectively applying heat to the area of contact.

19. The method of claim 18 further comprising the step of using vibration to perform the step of selectively applying heat to the area of contact.

20. The method of claim 18 in which the first metallic material is comprised of tin.

21. A unit for use in a stacked circuit module comprising:
a CSP;
a form standard attached to the CSP; and
flex circuitry attached to the form standard.

22. The unit of claim 21 in which the flex circuitry is comprised of a first flex circuit and a second flex circuit.

23. The unit of claim 21 in which the flex circuitry is attached to the form standard with at least one metallic bond.

24. The unit of claim 23 in which the metallic bond is comprised of at least two metals.

25. The unit of claim 21 in which the flex circuitry is comprised of first and second flex circuits, each of which is attached to the form standard with at least one metallic bond.
